(19) United States
(12) Patent Application Publication
(10) Pub. No.: US 2019/0028092 A1
(43) Pub. Date: Jan. 24, 2019

(54) FEED-FORWARD PHASE NOISE/SPUR CANCELLATION

(71) Applicant: QUALCOMM Incorporated, San Diego, CA (US)

(72) Inventors: Yue LU, Los Gatos, CA (US); Zuow-Zun CHEN, San Jose, CA (US); Jeongsik YANG, San Jose, CA (US)

(21) Appl. No.: 15/863,779

(22) Filed: Jan. 5, 2018

Related U.S. Application Data
(60) Provisional application No. 62/535,176, filed on Jul. 20, 2017.

(51) Int. Cl. H03K 5/1252; H03L 7/08; H03K 5/159

(52) U.S. Cl. CPC H03K 5/1252; H03K 5/159; H03L 7/08

(57) ABSTRACT

An open-loop feed-forward auto-correlator phase noise and spur cancellation device includes a clock source to generate a clock signal with noise and/or spurs. The device also includes a phase auto-correlator coupled to an output of the clock source to generate a delayed clock signal and to auto-correlate the clock signal and the delayed clock signal to generate an auto-correlated control signal at an output of the phase auto-correlator. The device further includes a signal control delay line coupled to the output of the phase auto-correlator to modulate a phase of the clock signal based on the auto-correlated control signal to cancel the noise and/or spurs generated by the clock source. The signal control delay line includes a supply voltage regulator and a clock distribution network.

### CROSS-REFERENCE TO RELATED APPLICATION

The present application claims the benefit of U.S. Provisional Patent Application No. 62/535,176, filed on Jul. 20, 2017, and titled “FEED-FORWARD PHASE NOISE/SPUR CANCELLATION,” the disclosure of which is expressly incorporated by reference herein in its entirety.

### TECHNICAL FIELD

The present disclosure generally relates to phase noise and spur cancellation for timing circuitry. More specifically, aspects of the present disclosure relate to open-loop feed-forward phase noise and spur cancellation for the timing circuitry using phase extraction and auto-correlation of a clock and delay clock signals to modulate a phase of the clock signal based on the auto-correlation.

### BACKGROUND

Voltage control oscillators (VCOs) are one of the most critical blocks in phase lock loops (PLLs). However, VCOs suffer from poor phase noise performance. Some implementations use a delay discriminator or phase discriminator and filters inside a closed-loop to reduce phase noise. For example, the phase discriminator may extract two clock phases or obtain a delayed version of a clock phase from a same clock source and mix the two clock phases or the clock phase and corresponding delayed clock phase. In some implementations, the two clock phases are obtained from different stages of a ring oscillator-based VCO. The mixed clock phases are filtered and then injected into a delay line to achieve active phase noise cancellation. This implementation is based on a feedback loop or cancellation loop that is included within a PLL with the VCO. This implementation is essentially a high order PLL because it provides a filter for the VCO inside of the PLL.

This implementation is affected by instability concerns. For example, because the implementation is within a feedback loop, it is unlikely to achieve an optimal bandwidth (e.g., high bandwidth or low bandwidth) correction because the stability of the loop may be adversely affected. The stability concerns constrain the effectiveness of the cancellation loop. The implementation is highly complex and is subject to increased power consumption and overhead.

### SUMMARY

An open-loop feed-forward auto-correlator phase noise and spur cancellation device may include a phase auto-correlator coupled to an output of a clock source to receive a clock signal with noise and/or spurs. The phase auto-correlator generates a delayed clock signal and auto-correlates the clock signal and the delayed clock signal to generate an auto-correlated control signal at an output of the phase auto-correlator. The device further includes a signal control delay line coupled to the output of the phase auto-correlator. The signal control delay line modulates a phase of the clock signal based on the auto-correlated control signal to cancel the noise and/or spurs generated by the clock source. The signal control delay line may include a supply voltage regulator and/or a clock distribution network.

An open-loop feed-forward auto-correlator phase noise and spur cancellation device may include a phase auto-correlator coupled to an output of a clock source to receive a clock signal with noise and/or spurs. The phase auto-correlator generates a delayed clock signal and auto-correlates the clock signal and the delayed clock signal to generate an auto-correlated control signal at an output of the phase auto-correlator. The device further includes means for modulating a phase of the clock signal based on the auto-correlated control signal to cancel the noise and/or spurs generated by the clock source. The modulating means may include means for regulating voltage of the modulating means and/or means for converting a signal to a phase domain.

A method to achieve feed-forward phase noise/spur cancellation may include receiving a clock signal including noise and/or spurs. The method also includes generating a delayed clock signal by a phase auto-correlator. The method further includes auto-correlating the clock signal and the delayed clock signal to generate an auto-correlated control signal at an output of the phase auto-correlator. Furthermore, the method includes modulating, by a signal control delay line, a phase of the clock signal based on the auto-correlated control signal to cancel the noise and/or spurs generated by the clock source.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a wireless device communicating with a wireless communication system.

FIG. 2 shows a block diagram of the wireless device in FIG. 1, according to an aspect of the present disclosure.

FIG. 3 illustrates a phase lock loop (PLL) system according to aspects of the present disclosure.

FIG. 4 illustrates an open-loop feed-forward auto-correlator phase noise and spur cancellation device according to aspects of the present disclosure.

FIG. 5 illustrates another open-loop feed-forward auto-correlator phase noise and spur cancellation device according to aspects of the present disclosure.

FIG. 6 is a graph illustrating a relationship between clock signal delay and phase detector (PD) output according to aspects of the present disclosure.

FIG. 7 depicts a simplified flowchart of a method to achieve feed-forward phase noise/spur cancellation according to aspects of the present disclosure.

FIG. 8 is a block diagram showing an exemplary wireless communication system in which a configuration of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR” and the use of the term “or” is intended to represent an “exclusive OR”.

Timing circuitry for analog-to-digital converters (ADCs), digital-to-analog converters (DACs), central processing units (CPUs), receive blocks (e.g., mixer, sampler, etc.) of a wireless communication device, transmit blocks (e.g., mixer, synchronizer, etc.) of the wireless communication device and other timing critical blocks are subject to phase uncertainty. The phase uncertainty may include phase noise (e.g., random noise), spurs (e.g., cyclostationary noise), etc. One of the contributors of phase uncertainty is a clock source of the timing circuitry.

Some implementations use a delay discriminator or phase discriminator and filter inside a closed-loop to reduce phase noise. These implementations, however, are affected by instability concerns. For example, because the implementation is within a feedback loop, it is unlikely to achieve an optimal bandwidth correction because the stability of the loop may be adversely affected. The stability concerns constrain a bandwidth choice of the cancellation loop. These implementations are highly complex and subject to increased power consumption and overhead.

Aspects of the present disclosure include an open-loop feed-forward auto-correlator phase noise and spur cancellation device that extracts a phase uncertainty of an output of a clock source. The phase uncertainty may be an alternating current (AC) signal. The output of the clock source may be an output of a reference clock, an output of an oscillator such as a crystal oscillator, an output of a voltage controlled oscillator (VCO) or an output of a phase lock loop (PLL).

In one aspect of the disclosure, the open-loop feed-forward auto-correlator phase noise and spur cancellation device includes a clock source, a phase auto-correlator (or discriminator) coupled to an output of the clock source and a signal control delay line (e.g., phase modulator) coupled to the output of the phase auto-correlator. The clock source generates a clock signal with noise and/or spurs. The clock source may be an oscillator such as a crystal oscillator, a VCO, or a PLL.

The phase auto-correlator generates a delayed clock signal and auto-correlates the clock signal and the delayed clock signal to generate an auto-correlated control signal at an output of the phase auto-correlator. The phase auto-correlator may sense phase uncertainty including the noise and/or spurs associated with the clock signal. In one aspect of the disclosure, the phase auto-correlator may include a mixer such as an exclusive OR (XOR) gate to mix the clock signal and the delayed clock signal. Other devices can be used in place of the XOR gate. For example, a tri-state phase and frequency detector or a sub-sampling phase detector can be used in place of the XOR gate.

The aspects of the present disclosure achieve wideband cancellation with a low implementation risk. The wideband cancellation is achieved because feed-forward characteristics of the phase uncertainty cancellation have no band restrictions associated with a phase lock loop (PLL). The present disclosure can be used in many applications that specify good phase noise and low power consumption including baseband and radio frequency clock generation.

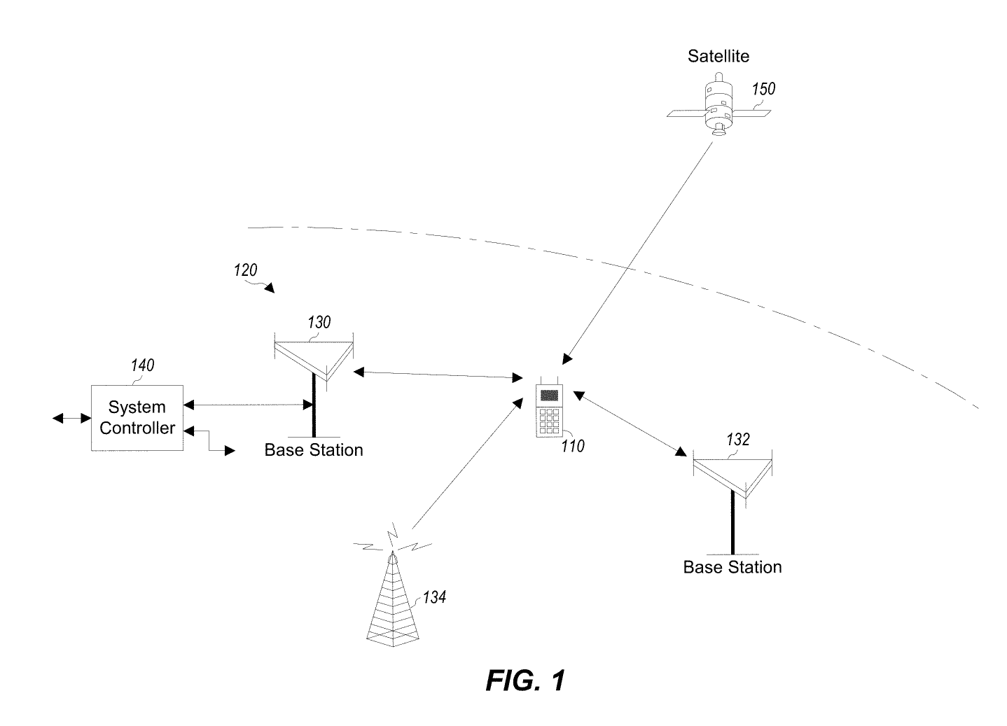

FIG. 1 shows a wireless device 110 communicating with a wireless communication system 120. The wireless device 110 includes feed-forward phase noise and spur cancellation. The wireless communication system 120 may be a 5G system, a long term evolution (LTE) system, a code division multiple access (CDMA) system, a global system for mobile communications (GSM) system, a wireless local area network (WLAN) system, or some other wireless system. A CDMA system may implement wideband CDMA (WCDMA), time division synchronous CDMA (TD-SCDMA), CDMA2000, or some other version of CDMA. For simplicity, FIG. 1 shows the wireless communication system 120 including two base stations 130 and 132 and one system controller 140. In general, a wireless system may include any number of base stations and any number of network entities.

A wireless device 110 may be referred to as a user equipment (UE), a mobile station, a terminal, an access terminal, a subscriber unit, a station, etc. The wireless device 110 may also be a cellular phone, a smartphone, a tablet, a wireless modem, a personal digital assistant (PDA), a handheld device, a laptop computer, a Smartbook, a netbook, a cordless phone, a wireless local loop (WLL) station, a Bluetooth device, etc. The wireless device 110 may be capable of communicating with the wireless communication system 120. The wireless device 110 may also be capable of receiving signals from broadcast stations (e.g., a broadcast station 134), signals from satellites (e.g., a satellite 150) in one or more global navigation satellite systems (GNSS), etc. The wireless device 110 may support one or more radio technologies for wireless communication such as 5G, LTE, CDMA2000, WCDMA, TD-SCDMA, GSM, 802.11, etc.

The wireless device 110 may support carrier aggregation, which is operation on multiple carriers. Carrier aggregation may also be referred to as multi-carrier operation. According to an aspect of the present disclosure, the wireless device 110 may be able to operate in low-band from 698 to 960 megahertz (MHz), mid-band from 1475 to 2170 MHz, and/or high-band from 2300 to 2690 MHz, ultra-high band from 3400 to 3800 MHz, and long-term evolution (LTE) in LTE unlicensed bands (LTE-U/LAA) from 5150 MHz to 5950 MHz. Low-band, mid-band, high-band, ultra-high band, and LTE-U refer to five groups of bands (or band groups), with each band group including a number of frequency bands (or simply, “bands”). For example, in some systems each band may cover up to 200 MHz and may include one or more carriers. For example, each carrier may cover up to 40 MHz in LTE. Of course, the range for each of the bands is merely exemplary and not limiting, and other frequency ranges may be used. LTE Release 11 supports 35 bands, which are referred to as LTE/UMTS bands and are listed in 3GPP TS 36.101. The wireless device 110 may be configured with up to five carriers in one or two bands in LTE Release 11.

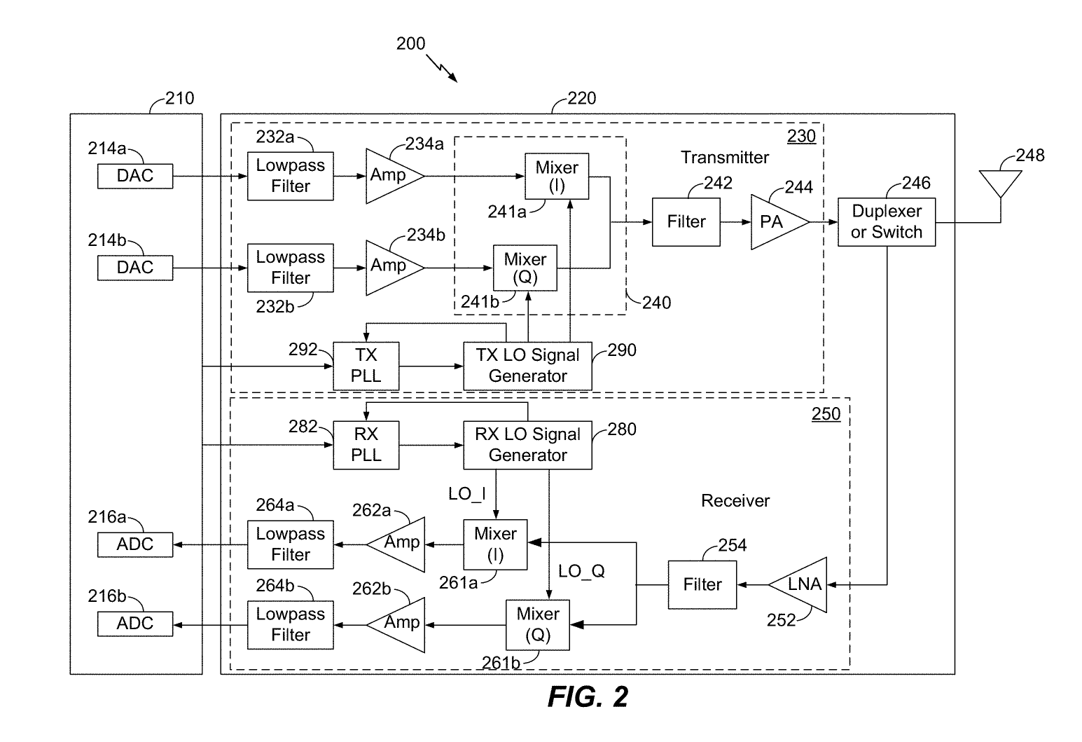

FIG. 2 shows a block diagram of an exemplary design of a wireless device 200, such as the wireless device 110 shown in FIG. 1. FIG. 2 shows an example of a transceiver 220, which may be a wireless transceiver (WTR). In general, the conditioning of the signals in a transmitter 230 and a receiver 250 may be performed by one or more stages of amplifier(s), filter(s), upconverters, downconverters, and the like. These circuit blocks may be arranged differently from the configuration shown in FIG. 2. Furthermore, other circuit blocks not shown in FIG. 2 may also be used to condition the signals in the transmitter 230 and receiver 250. Unless otherwise noted, any signal in FIG. 2, or any other illustrations in the drawings, may be either single-ended or differential. Some circuit blocks in FIG. 2 may also be omitted.

In the example shown in FIG. 2, the wireless device 200 generally includes the transceiver 220 and a data processor 210. The data processor 210 may include a memory (not shown) to store data and program codes, and may generally include analog and digital processing elements. The transceiver 220 may include the transmitter 230 and receiver 250 that support bi-directional communication. In general, the wireless device 200 may include any number of transmitters and/or receivers for any number of communication systems and frequency bands. All or a portion of the transceiver 220 may be implemented on one or more analog integrated circuits (ICs), radio frequency (RF) integrated circuits (RFICs), mixed-signal ICs, and the like.

A transmitter or a receiver may be implemented with a super-heterodyne architecture or a direct-conversion architecture. In the super-heterodyne architecture, a signal is frequency-converted between radio frequency and baseband in multiple stages, e.g., from radio frequency to an intermediate frequency (IF) in one stage, and from intermediate frequency to baseband in another stage for a receiver. In the direct-conversion architecture, a signal is frequency-converted between radio frequency and baseband in one stage. The super-heterodyne and direct-conversion architectures may use different circuit blocks and/or have different requirements. In the example shown in FIG. 2, the transmitter 230 and the receiver 250 are implemented with the direct-conversion architecture.

In a transmit path, the data processor 210 processes data to be transmitted. The data processor 210 also provides in-phase (I) and quadrature (Q) analog output signals to the transmitter 230 in the transmit path. In an exemplary aspect, the data processor 210 includes digital-to-analog converters (DACs) 214a and 214b for converting digital signals generated by the data processor 210 into the in-phase (I) and quadrature (Q) analog output signals (e.g., I and Q output currents) for further processing.

Within the transmitter 230, lowpass filters 232a and 232b filter the in-phase (I) and quadrature (Q) analog transmit signals, respectively, to reduce undesired images caused by the prior digital-to-analog conversion. Amplifiers (Amp) 234a and 234b amplify the signals from lowpass filters 232a and 232b, respectively, and provide in-phase (I) and quadrature (Q) baseband signals. An upconverter 240 including upconversion mixers 241a and 241b upconverts the in-phase (I) and quadrature (Q) baseband signals with in-phase (I) and quadrature (Q) transmit (TX) local oscillator (LO) signals from a TX LO signal generator 290 to provide an upconverted signal. A filter 242 filters the upconverted signal to reduce undesired images caused by the frequency upconversion as well as interference in a receive frequency band. A power amplifier (PA) 244 amplifies the signal from filter 242 to obtain the desired output power level and provides a transmit radio frequency signal. The transmit radio frequency signal is routed through a duplexer/switch 246 and transmitted via an antenna 248.

In a receive path, the antenna 248 receives communication signals and provides a received radio frequency (RF) signal, which is routed through the duplexer/switch 246 and provided to a low noise amplifier (LNA) 252. The duplexer/switch 246 is designed to operate with a specific receive (RX) to transmit (TX) (RX-to-TX) duplexer frequency separation, such that RX signals are isolated from TX signals. The received RF signal is amplified by the LNA 252 and filtered by a filter 254 to obtain a desired RF input signal. Downconversion mixers 261a and 261b mix the output of the filter 254 with in-phase (I) and quadrature (Q) receive (RX) LO signals (i.e., LO_I and LO_Q) from an RX LO signal generator 280 to generate in-phase (I) and quadrature (Q) baseband signals. The in-phase (I) and quadrature (Q) baseband signals are amplified by amplifiers 262a and 262b and further filtered by lowpass filters 264a and 264b to obtain in-phase (I) and quadrature (Q) analog input signals, which are provided to the data processor 210. In the exemplary configuration shown, the data processor 210 includes analog-to-digital converters (ADCs) 216a and 216b for converting the analog input signals into digital signals for further processing by the data processor 210.

In FIG. 2, the transmit local oscillator (TX LO) signal generator 290 generates the in-phase (I) and quadrature (Q) TX LO signals used for frequency upconversion, while a receive local oscillator (RX LO) signal generator 280 generates the in-phase (I) and quadrature (Q) RX LO signals used for frequency downconversion. Each LO signal is a periodic signal with a particular fundamental frequency. A phase locked loop (PLL) 292 receives timing information from the data processor 210 and generates a control signal used to adjust the frequency and/or phase of the TX LO signals from the TX LO signal generator 290. Similarly, a PLL 282 receives timing information from the data processor 210 and generates a control signal used to adjust the frequency and/or phase of the RX LO signals from the RX LO signal generator 280.

The wireless device 200 may support carrier aggregation and may (i) receive multiple downlink signals transmitted by one or more cells on multiple downlink carriers at different frequencies, and/or (ii) transmit multiple uplink signals to one or more cells on multiple uplink carriers. For intra-band carrier aggregation, the transmissions are sent on different carriers in the same band. For inter-band carrier aggregation, the transmissions are sent on multiple carriers in different bands. Those skilled in the art will understand, however, that aspects described herein may be implemented in systems, devices, and/or architectures that do not support carrier aggregation.

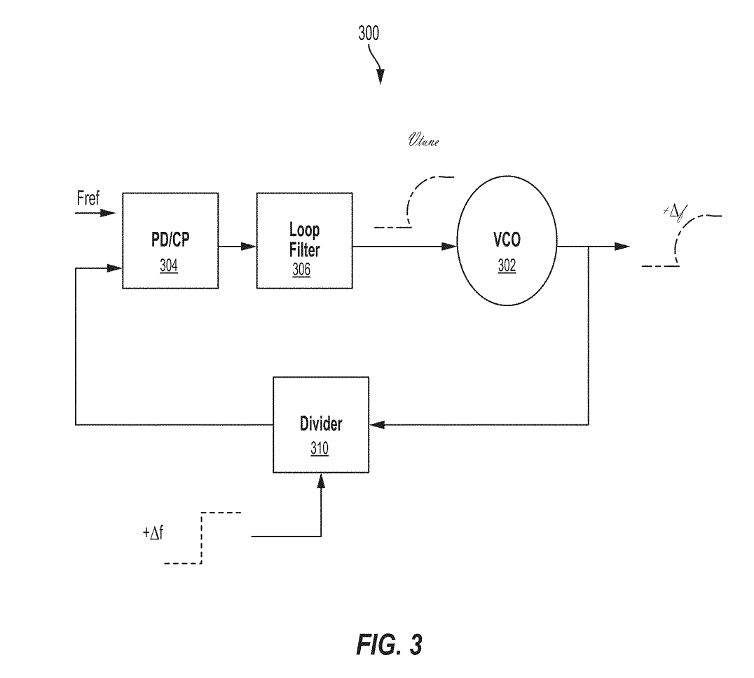

FIG. 3 illustrates a phase lock loop (PLL) system 300. The PLL system 300 includes a voltage controlled oscillator (VCO) 302, a phase detector 304, a loop filter (e.g., low pass filter) 306, and a frequency divider 310 (e.g., integer-N synthesizer or fractional synthesizer). The PLL system 300 may be integrated in a mobile communication device. For example, the PLL system 300 may be implemented in a radio frequency (RF) module of the mobile communication device.

The phase detector 304 may be coupled to the loop filter 306, the loop filter 306 may be coupled to the VCO 302, the VCO 302 may be coupled to the frequency divider 310 and the frequency divider 310 may be coupled to the phase detector 304 to close a feedback loop. The output of the VCO 302 may be a frequency sinusoid that is controlled by a tuning voltage Vtune, which is received by the VCO 302 from the loop filter 306. For example, changing the tuning voltage Vtune changes the frequency of the VCO 302. To synthesize a desirable or exact frequency of the VCO 302, the output frequency of the VCO 302 is fed back to the frequency divider 310. The phase detector 304 compares an output of the frequency divider 310 with a reference signal (e.g., reference signal Fref). In some aspects, the reference frequency may be generated by a stable local crystal oscillator (not shown).

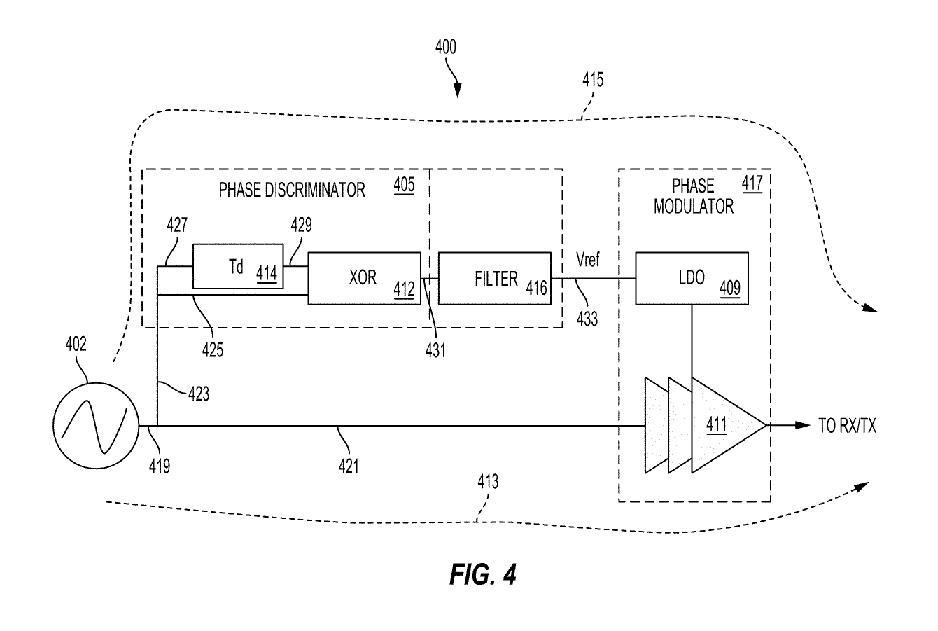

FIG. 4 illustrates an open-loop feed-forward auto-correlator phase noise and spur cancellation device 400 according to aspects of the present disclosure. The open-loop feed-forward auto-correlator phase noise and spur cancellation device 400 includes a clock source 402, a phase auto-correlator (or discriminator) 405 coupled to an output of the clock source 402 and a signal control delay line (e.g., phase modulator) 417 coupled to the output of the phase auto-correlator 405. The clock source 402 generates a clock signal 419 with noise and/or spurs. The clock source 402 may be an oscillator such as a crystal oscillator, a VCO, or a PLL. A first portion 421 of the clock signal 419 traverses a first (or default) path 413 for the clock signal 419 and a second portion 423 of the clock signal 419 traverses a second path 415. The second portion 423 may be split into a third portion 425 and a fourth portion 427.

The first portion 421 of the clock signal 419 and the second portion 423 of the clock signal 419 have a same phase. The phase auto-correlator 405 generates a delayed clock signal 429 and auto-correlates the third portion 425 of the clock signal 419 and the delayed clock signal 429 to generate an auto-correlated control signal 431 at an output of the phase auto-correlator 405. The phase auto-correlator 405 may sense phase uncertainty including the noise and/or spurs associated with the clock signal 419. In one aspect of the disclosure, the phase auto-correlator 405 may include a mixer such as an exclusive OR (XOR) gate 412 to mix the third portion 425 of the clock signal 419 and the delayed clock signal 429. The fourth portion 427 may be delayed by a delay device 414.

The signal control delay line 417 may be a voltage/current/charge control delay line. The signal control delay line 417 modulates a phase of the clock signal 419 based on the auto-correlated control signal 431 to cancel the noise and/or spurs generated by the clock source 402. For example, an anti-phase noise signal based on the phase uncertainty is generated by the signal control delay line 417 and injected into an output of the clock source 402 along the first path 413 to modulate the clock signal 419 from the clock source 402 or cancel out the phase uncertainty from the clock signal 419. The signal control delay line 417 may modulate the first portion 421 of the clock signal 419 and/or cancel out the phase uncertainty from the first portion 421 of the clock signal 419. The signal control delay line 417 includes a supply voltage regulator (e.g., a low dropout (LDO) regulator 409) and a buffer 411, in one configuration.

The open-loop feed-forward auto-correlator phase noise and spur cancellation device 400 further includes a filter 416 coupled between the phase auto-correlator 405 and the signal control delay line 417 to filter the auto-correlated control signal 431. A filtered auto-correlated control signal 433 is provided to the signal control delay line 417 for modulation. In one aspect of the disclosure, different filters can be adapted for different blocks or devices (e.g., transmitter, receiver, etc.) Each of the filters may be optimized for their own figure of merit (FoM).

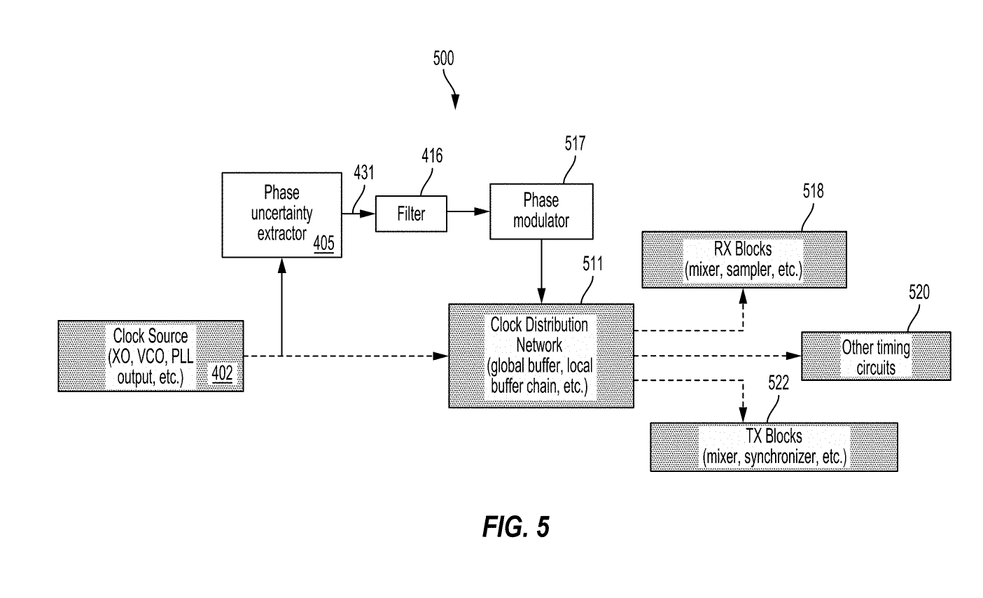

FIG. 5 illustrates another open-loop feed-forward auto-correlator phase noise and spur cancellation device 500 according to aspects of the present disclosure. For illustrative purposes, some of the labelling and numbering of the devices and features of FIG. 5 are similar to those of FIG. 4. For example, the open-loop feed-forward auto-correlator phase noise and spur cancellation device 500 includes the clock source 402, and the phase auto-correlator 405 coupled to an output of the clock source 402. The open-loop feed-forward auto-correlator phase noise and spur cancellation device 500 further includes a signal control delay line 517 coupled to a clock distribution network 511. In one aspect, the signal control delay line 517 may include an LDO that is coupled with the clock distribution network 511.

In one aspect of the disclosure, the clock distribution network 511 may be coupled to an output of the clock source 402. In this aspect, the anti-phase noise signal based on the phase uncertainty is injected into the clock distribution network 511. The clock distribution network 511 may be a local clock distribution network for particular circuitry or may be a global clock distribution network that is shared between multiple circuits (e.g., between same or different circuitry). The multiple circuits may include receive blocks 518, transmit blocks 522, and other timing circuits 520 (e.g., ADC, DAC and CPU, etc.) The clock distribution network 511 may include a global buffer for global distribution and/or a local buffer for local distribution. In one aspect of the disclosure, the clock distribution network 511 may be part of the signal control delay line 517. In operation, a phase uncertainty may be extracted from a clock source 402 and the anti-phase noise signal based on the phase uncertainty is injected in the clock distribution network 511.

In some aspects of the disclosure, the open-loop feed-forward auto-correlator phase noise and spur cancellation device 500 further includes a combiner (not shown) to combine the auto-correlated control signal 431 (e.g., an alternating current (AC) signal) with a reference signal (e.g., a direct current (DC) voltage). The modulation (e.g., amplitude modulation) is based on the reference signal and the auto-correlated control signal 431. The combiner may be coupled between the filter 416 and the signal control delay line 417/517.

The output of the combiner may have a linear relationship to the reference signal. For example, the output of the combiner may be a combination of the DC voltage and the AC signal. In one aspect of the disclosure, a buffer (e.g., the buffer 411) may function (at least in part) as the signal control delay line 417/517 and may be used to convert the combination of the DC voltage and the AC signal back to a phase domain to cancel out or modulate the phase noise of the clock signal 419. The buffer may be the local buffer and/or the global buffer corresponding to the clock distribution network 511 when the clock distribution network 511 is included in the signal control delay line (417 or 517). In one aspect, the signal (e.g., voltage) control delay line (417 or 517) may be part of an existing signal control delay line instead of an independent signal control delay line. For example, the existing signal control delay line may be part of the circuitry of the receive blocks, the transmit blocks and/or the other timing critical blocks. The delay change of the buffer corresponds to phase modulation.

The present disclosure offers high levels of stability and achieves wideband cancellation with a relatively simple design with low implementation risk. Aspects of the present disclosure also save power and area through utilization of global buffers as the delay line relative to other implementations. For example, other implementations use local distribution buffers that specify design of dedicated delay lines that consume more power and area. The filters 416 for the open-loop feed-forward auto-correlator phase noise and spur cancellation device 500 may be customizable for each block where the customization parameters are based on a specification of each block (e.g., transmitter, receiver, etc.) The blocks, however, may share the phase discriminator. The open-loop feed-forward auto-correlator phase noise and spur cancellation device 500 achieves improved overall figure of merit.

The design with a reduced number of devices includes an implicit phase modulator stage that is achieved with local oscillator distribution buffers and corresponding low dropout (LDO) regulators. The LDO regulator may be used as the noise cancellation point (without amplitude and phase modulation blocks).

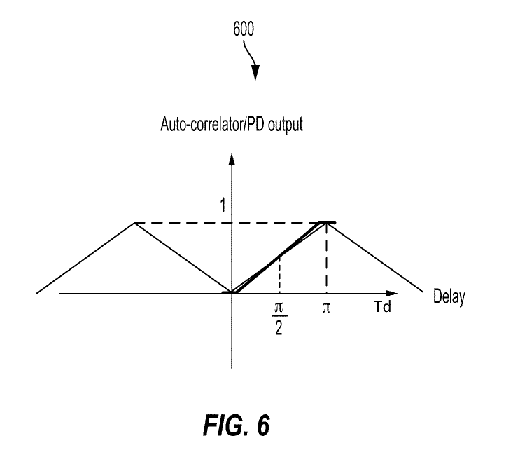

FIG. 6 is a graph 600 illustrating a relationship between clock signal delay and phase detector (PD) output. This relationship may be used to select an optimized clock signal delay to achieve a desirable phase detector gain. The horizontal axis of the graph 600 represents the control signal delay (Td) represented in radians (e.g., Td/Tclk*2pi) while the vertical axis represents an average auto-correlator/PD output value (in voltage or current). In some implementations, the control signal delay represented in radians is specified to be around pi/2 phase. Some programmability may be specified for some process-voltage-temperature (PVT) conditions. In some implementations, while the control signal delay represented in radians may not be precise, the control signal delay represented in radians should be a fraction (e.g., clock signal/4) of the clock period. Some foreground calibration is useful to find an optimum or desirable delay over PVT.

FIG. 6 illustrates how auto-correlated phase noise represented as Td is transferred to an output (e.g., voltage) of the exclusive OR gate in accordance with a linear relationship. A slope of the lines of the graph 600 is a phase noise transfer gain of the exclusive OR gate. Because the output of the exclusive OR gate represents phase noise information, an overall transfer function can be determined based on the phase noise transfer gain that can be used for cancellation through the phase modulator.

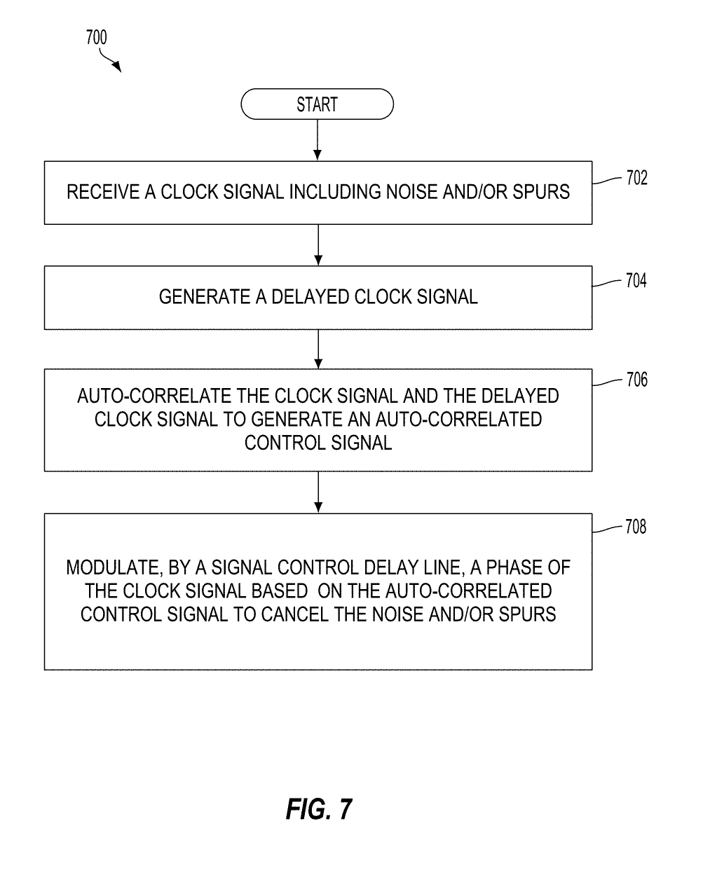

FIG. 7 depicts a simplified flowchart of a method 700 to achieve feed-forward phase noise/spur cancellation according to aspects of the present disclosure. At block 702, a clock signal including noise and/or spurs is received. At block 704, a phase auto-correlator of the open-loop feed-forward auto-correlator phase noise and spur cancellation device generates a delayed clock signal. At block 706, the phase auto-correlator auto-correlates the clock signal and the delayed clock signal to generate an auto-correlated control signal at an output of the phase auto-correlator. At block 708, a signal control delay line of the open-loop feed-forward auto-correlator phase noise and spur cancellation device modulates a phase of the clock signal based on the auto-correlated control signal to cancel the noise and/or spurs generated by the clock source, the signal control delay line including a supply voltage regulator.

According to a further aspect of the present disclosure, the open-loop feed-forward auto-correlator phase noise and spur cancellation device includes means for modulating a phase of the clock signal. The modulating means may be the signal control delay line 417/517 or phase modulator, the low dropout regulator 409, the buffer 411 and/or the clock distribution network 511. In another aspect, the aforementioned means may be any module, or any apparatus configured to perform the functions recited by the aforementioned means.

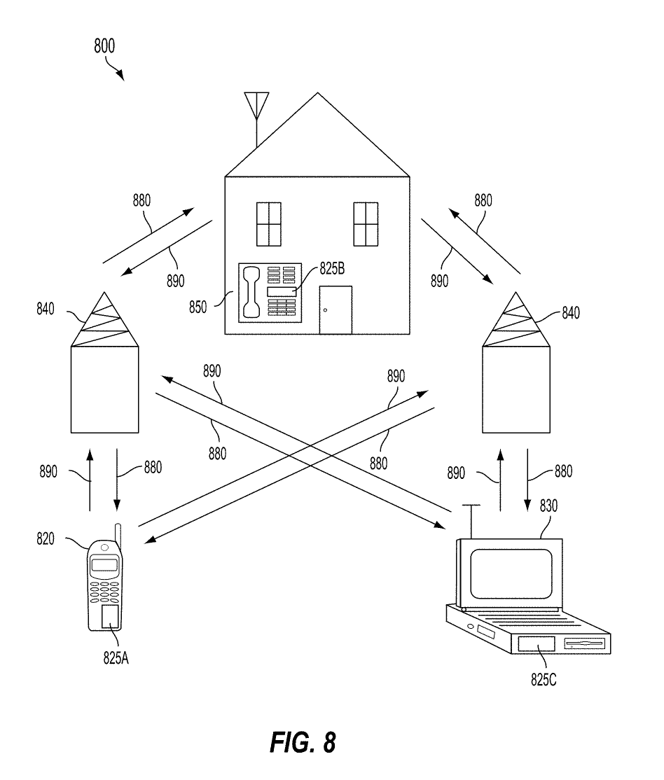

FIG. 8 is a block diagram showing an exemplary wireless communication system in which a configuration of the disclosure may be advantageously employed. For purposes of illustration, FIG. 8 shows three remote units 820, 830, and 850 and two base stations 840. It will be recognized that wireless communication systems may have many more remote units and base stations. Remote units 820, 830, and 850 include IC devices 825A, 825B, and 825C that include the disclosed open-loop feed-forward auto-correlator phase noise and spur cancellation device. It will be recognized that other devices may also include the disclosed open-loop feed-forward auto-correlator phase noise and spur cancellation device, such as the base stations, switching devices, and network equipment. FIG. 8 shows forward link signals 880 from the base station 840 to the remote units 820, 830, and 850 and reverse link signals 890 from the remote units 820, 830, and 850 to base station 840.

In FIG. 8, remote unit 820 is shown as a mobile telephone, remote unit 830 is shown as a portable computer, and remote unit 850 is shown as a fixed location remote unit in a wireless local loop system. For example, a remote unit may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieves data or computer instructions, or combinations thereof. Although FIG. 8 illustrates remote units according to the aspects of the disclosure, the disclosure is not limited to these exemplary illustrated units. Aspects of the disclosure may be suitably employed in many devices, which include the open-loop feed-forward auto-correlator phase noise and spur cancellation device.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic device, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. Storage media may be any available media that can be accessed by a general-purpose or special-purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD) and Blu-ray disc where disks usually reproduce data magnetically, while discs reproduce data optically with lasers. Combinations of the above should also be included within the scope of computer-readable media.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “a step for.”

What is claimed is:

1. An open-loop feed-forward auto-correlator phase noise and spur cancellation device, comprising:
a phase auto-correlator coupled to an output of a clock source to receive a clock signal with noise and/or spurs, to generate a delayed clock signal and to auto-correlate the clock signal and the delayed clock signal to generate an auto-correlated control signal at an output of the phase auto-correlator; and
a signal control delay line coupled to the output of the phase auto-correlator to modulate a phase of the clock signal based at least in part on the auto-correlated control signal to cancel the noise and/or spurs generated by the clock source.

2. The open-loop feed-forward auto-correlator phase noise and spur cancellation device of claim 1, in which the clock distribution network comprises a global clock distribution network that is shared between different circuits.

3. The open-loop feed-forward auto-correlator phase noise and spur cancellation device of claim 1, in which the clock distribution network comprises a local clock distribution network for the open-loop feed-forward auto-correlator phase noise and spur cancellation device.

4. The open-loop feed-forward auto-correlator phase noise and spur cancellation device of claim 1, further comprising a filter coupled between the phase auto-correlator and the signal control delay line to filter the auto-correlated control signal.

5. The open-loop feed-forward auto-correlator phase noise and spur cancellation device of claim 1, further comprising a combiner to combine the auto-correlated control signal with a reference signal, in which modulation is based at least in part on the reference signal and the auto-correlated control signal.

6. The open-loop feed-forward auto-correlator phase noise and spur cancellation device of claim 1, in which the supply voltage regulator comprises a low drop out (LDO) regulator.

7. The open-loop feed-forward auto-correlator phase noise and spur cancellation device of claim 1, in which the clock distribution network comprises at least one buffer.

8. The open-loop feed-forward auto-correlator phase noise and spur cancellation device of claim 1, incorporated in timing circuitry for an analog-to-digital converter (ADC), a digital-to-analog converter (DAC), a central processing unit (CPU), a receive block of a wireless communication device or a transmit block of the wireless communication device.

9. The open-loop feed-forward auto-correlator phase noise and spur cancellation device of claim 1, in which the signal delay line comprises a supply voltage regulator and/or a clock distribution network

10. A method to achieve feed-forward phase noise/spur cancellation, comprising:
receiving a clock signal including noise and/or spurs;
generating a delayed clock signal by a phase auto-correlator;
auto-correlating the clock signal and the delayed clock signal to generate an auto-correlated control signal at an output of the phase auto-correlator; and
modulating, by a signal control delay line, a phase of the clock signal based at least in part on the auto-correlated control signal to cancel the noise and/or spurs generated by the clock source.

11. The method to achieve feed-forward phase noise/spur cancellation of claim 10, further comprising filtering the auto-correlated control signal.

12. The method to achieve feed-forward phase noise/spur cancellation of claim 10, further comprising combining the auto-correlated control signal with a reference signal, in which the modulating is based at least in part on the reference signal and the auto-correlated control signal.

13. The method to achieve feed-forward phase noise/spur cancellation of claim 10, implemented using an open-loop feed-forward auto-correlator phase noise and spur cancellation device.

14. The method to achieve feed-forward phase noise/spur cancellation of claim 12, further comprising incorporating the open-loop feed-forward auto-correlator phase noise and spur cancellation device in timing circuitry for an analog-to-digital converter (ADC), a digital-to-analog converter (DAC), a central processing unit (CPU), a receive block of a wireless communication device or a transmit block of the wireless communication device.

15. An open-loop feed-forward auto-correlator phase noise and spur cancellation device, comprising:
a clock source to generate;
a phase auto-correlator coupled to an output of a clock source to receive a clock signal with noise and/or spurs, to generate a delayed clock signal and to auto-correlate the clock signal and the delayed clock signal to generate an auto-correlated control signal at an output of the phase auto-correlator; and
means for modulating a phase of the clock signal based at least in part on the auto-correlated control signal to cancel the noise and/or spurs generated by the clock source.

16. The open-loop feed-forward auto-correlator phase noise and spur cancellation device of claim 15, further comprising a filter coupled between the phase auto-correlator and the modulating means to filter the auto-correlated control signal.

17. The open-loop feed-forward auto-correlator phase noise and spur cancellation device of claim 15, further comprising a combiner to combine the auto-correlated control signal with a reference signal, in which modulation is based at least in part on the reference signal and the auto-correlated control signal.

18. The open-loop feed-forward auto-correlator phase noise and spur cancellation device of claim 15, in which the device is incorporated in timing circuitry for an analog-to-digital converter (ADC), a digital-to-analog converter (DAC), a central processing unit (CPU), a receive block of a wireless communication device, or a transmit block of the wireless communication device.

19. The open-loop feed-forward auto-correlator phase noise and spur cancellation device of claim 15, in which the converting means comprises at least one buffer.

20. The open-loop feed-forward auto-correlator phase noise and spur cancellation device of claim 15, in which the converting means comprises a global clock distribution network that is shared between different circuits.

21. The open-loop feed-forward auto-correlator phase noise and spur cancellation device of claim 15, in which the converting means comprises a local clock distribution network for the open-loop feed-forward auto-correlator phase noise and spur cancellation device.

22. The open-loop feed-forward auto-correlator phase noise and spur cancellation device of claim 15, in which the modulating means comprising means for regulating voltage of the modulating means and/or means for converting a signal to a phase domain.
